(19) United States
(12) Patent Application Publication
(10) Pub. No.: US 2025/0029971 A1
(43) Pub. Date: Jan. 23, 2025

(54) MODULAR CHIPLET SYSTEM

(71) Applicant: Zero ASIC Corporation, Lexington, MA (US)

(72) Inventor: Andreas Olofsson, Lexington, MA (US)

(21) Appl. No.: 18/771,693

(22) Filed: Jul. 12, 2024

Related U.S. Application Data
(60) Provisional application No. 63/514,827, filed on Jul. 21, 2023.

(51) Int. Cl. H01L 25/18; H01L 23/00; H01L 23/528; H01L 23/538; H01L 25/00; H10B 80/00

(52) U.S. Cl. CPC H01L 25/18; H01L 23/5286; H01L 23/5386; H01L 25/50; H01L 24/16; H01L 24/32; H01L 24/73; H01L 2224/16145; H01L 2224/16225; H01L 2224/32145; H01L 2224/73204; H01L 2225/06513; H01L 2225/06517; H01L 2225/06541; H01L 2924/1431; H01L 2924/1437; H10B 80/00

(57) ABSTRACT

A modular chiplet system enables numerous unique systems to be created from a small set of chiplets and a fabric device. The modular chiplet system includes an active semiconductor substrate with a built-in network-on-chip, chiplet interfaces for connecting to stacked chiplets, power delivery networks, clocking, system management, and general-purpose I/O. A set of mechanically and electrically interchangeable rotationally symmetrical chiplets can be connected to the active semiconductor interposer, at one site of an array of N×M sites. The rotational symmetry enables I/O chiplets to be placed at any side of the active semiconductor substrate. The modular chiplet system includes a shared memory architecture that allows the chiplets to communicate with each other using memory mapped addressing and read/write transactions that are routed by the network-on-chip. The network-on-chip also enables communication between resources on or accessible via the active semiconductor substrate.

### CROSS-REFERENCE TO RELATED APPLICATION(S)

This application claims the benefit under 35 U.S.C. § 119 of U.S. Provisional Application No. 63/514,827, filed on Jul. 21, 2023, naming Andreas Olofsson as inventor, which application is hereby incorporated by reference.

This application is related to U.S. patent application Ser. No. 18/753,356, entitled “Integrated Circuit Die Stitching Using Jumper Die,” filed on Jun. 25, 2024, naming Andreas Olofsson and Lizabeth Keser as inventors, which application is hereby incorporated by reference.

### BACKGROUND

### Field of the Invention

This invention relates to design, manufacture, and packaging of integrated circuit products.

### Description of the Related Art

In general, chiplets are relatively small integrated circuit die that contain well-defined functionality and may be combined with other chiplets to form a larger, more complex System-on-Chip (SoC). The use of chiplets may reduce the cost of product development by reusing verified integrated circuit die. A substantial number of integrated circuit products can be created with a small number of chiplets. For example, five different processor products with a different number of cores (e.g., 8, 16, 32, 64, and 128 cores) can be constructed with only two co-designed chiplets: an input/output (I/O) hub, and a central processing unit (CPU) core cluster chiplet. Although use of chiplets reduces costs as compared to monolithic approaches, the approach has disadvantages. For example, consolidation of designs, which may be provided by different vendors, into a small number of systems (e.g., an I/O hub and a cluster of CPUs) limits system composability. In addition, high-performance chiplet-based products need custom designed passive interposers, which are costly to design, tool, manufacture, and test, but are less expensive than design of a unique SoC. Commercial viability of using chiplets to design a variety of systems with substantially different feature requirements requires composability and low per-system design cost. In addition, power consumption of chiplet die-to-die communication needs to be substantially less than the power consumption of a chiplet.

Referring to FIG. 1, a typical passive interposer used in conventional 2D and 2.5D packaging includes only point-to-point wiring and no buffering. An exemplary large physical interface uses approximately 2000 μm of conductive traces, which is a relatively long interconnect as compared to the length of conductive traces on an integrated circuit die. The effective distance between standard chiplet interfaces is approximately 4700 μm. Since advanced process nodes achieve relatively high transistor density, complex chiplets manufactured using these advanced process nodes occupy only a few mm². In a 2D/2.5D chiplet approach, long side-to-side communication distances render small chiplets impractical due to communication interface area and energy overhead. Accordingly, improved techniques for designing SoCs using chiplets are desired.

### SUMMARY OF EMBODIMENTS OF THE INVENTION

In at least one embodiment, an integrated circuit product includes an active semiconductor substrate including a network-on-chip and a plurality of die interfaces coupled to the network-on-chip. Each die interface of the plurality of die interfaces is disposed in a corresponding tile of an N-by-M tile map of a surface of the active semiconductor substrate. Each die interface of the plurality of die interfaces is separated from an adjacent die interface of the plurality of die interfaces by a lane having a predetermined width. N and M are integers of at least one. Each die interface of the plurality of die interfaces may have a grid array of connectors with a predetermined rotationally symmetric pinout. Each die interface of the plurality of die interfaces may have a corresponding address in a memory map of the N-by-M tile map of the surface of the active semiconductor substrate. A type of each connector of the grid array of connectors may be the same type as a corresponding connector at a location of a predetermined number of degrees of rotation around an axis of symmetry from the predetermined rotationally symmetric pinout. The integrated circuit die may include a programmable bus and a rotationally symmetric pinout. The programmable bus may be configured to logically map the rotationally symmetric pinout to the predetermined rotationally symmetric pinout.

In at least one embodiment, an integrated circuit product includes an integrated circuit die having a die interface including a grid array of connectors and a programmable bus configured to logically map the grid array of connectors to a predetermined rotationally symmetric pinout. The die interface may have a predetermined size and the integrated circuit die may include at least one additional die interface having the predetermined size and being disposed laterally with respect to the die interface and being separated from the die interface by a lane having a predetermined width.

In at least one embodiment, method of manufacturing an integrated circuit product includes attaching a plurality of integrated circuit die to an active semiconductor substrate using a plurality of corresponding integrated circuit die interfaces. Each integrated circuit die of the plurality of integrated circuit die has a size that is at least an integer multiple of a minimum predetermined die size. The active semiconductor substrate includes a network-on-chip and has a surface with an N-by-M tile map of the plurality of corresponding integrated circuit die interfaces. Each of the plurality of corresponding die interfaces may have a predetermined rotationally symmetric pinout. The method may include programming a programmable bus of each integrated circuit die of the plurality of integrated circuit die to logically map a corresponding rotationally symmetric pinout to the predetermined rotationally symmetric pinout according to an orientation of the integrated circuit die with respect to the active semiconductor substrate.

### BRIEF DESCRIPTION OF THE DRAWINGS

The present invention may be better understood, and its numerous objects, features, and advantages made apparent to those skilled in the art by referencing the accompanying drawings.

FIG. 1 illustrates a cross-sectional view of a portion of an integrated circuit product including chiplets and a passive interposer.

FIG. 2 illustrates a cross-sectional view of a portion of an integrated circuit product including chiplets and a fabric device consistent with at least one embodiment of the invention.

FIG. 3 illustrates a perspective view of a multi-chiplet interface of a fabric device having an array of discrete chiplet interfaces and discrete chiplets consistent with at least one embodiment of the invention.

FIG. 4 illustrates exemplary standard chiplet sizes and configuration on a fabric device to form a product using a modular chiplet system consistent with at least one embodiment of the invention.

FIG. 5 illustrates an exemplary process for designing an integrated circuit product using a library of chiplets having standard interface sizes and a fabric device consistent with at least one embodiment of the invention.

FIG. 6 illustrates an exemplary process for manufacturing an integrated circuit device including chiplets having standard interface sizes and a fabric device consistent with at least one embodiment of the invention.

FIG. 7 illustrates a functional block diagram of a network-on-chip of a fabric device consistent with at least one embodiment of the invention.

FIG. 8 illustrates a functional block diagram of a node of the network-on-chip of the fabric device of FIG. 7 consistent with at least one embodiment of the invention.

FIG. 9 illustrates a cross-sectional view of an integrated circuit product including chiplets and a fabric device having through-silicon vias consistent with at least one embodiment of the invention.

FIG. 10 illustrates an exemplary process flow for manufacturing an integrated circuit product including chiplets and a fabric device consistent with FIG. 9.

FIG. 11 illustrates a cross-sectional view of an integrated circuit product including chiplets and a fabric device without through-silicon vias consistent with at least one embodiment of the invention.

FIG. 12 illustrates an exemplary process flow for manufacturing an integrated circuit product including chiplets and a fabric device consistent with FIG. 11.

FIG. 13 illustrates an exemplary interface of a second order rotationally symmetric pinout consistent with at least one embodiment of the invention.

FIG. 14 illustrates an exemplary interface of a fourth order rotationally symmetric pinout consistent with at least one embodiment of the invention.

FIG. 15 illustrates an exemplary interface of a rotationally symmetric pinout consistent with at least one embodiment of the invention.

FIG. 16 illustrates an exemplary pin type distribution of a rotationally symmetric pinout of FIG. 15.

FIG. 17 illustrates an exemplary memory mapping of an integrated circuit product including chiplets and a fabric device consistent with at least one embodiment of the invention.

FIG. 18 illustrates a plan view of an exemplary fabric device of an integrated circuit product consistent with at least one embodiment of the invention.

FIG. 19 illustrates a plan view of an exemplary integrated circuit product including I/O chiplets consistent with at least one embodiment of the invention.

FIG. 20 illustrates a cross-sectional view of the exemplary integrated circuit product including I/O chiplets of FIG. 19.

The use of the same reference symbols in different drawings indicates similar or identical items.

### DETAILED DESCRIPTION

A modular chiplet system enables unique system permutations to be created from a small set of chiplets and a multi-interface fabric device. The modular chiplet system includes a fabric device that provides services to the 3D assembled chiplets. Embodiments of a fabric device include a built-in network-on-chip, 3D chiplet interfaces for connecting to chiplets stacked with the fabric device formed using an active semiconductor substrate (i.e., an active interposer or semiconductor substrate including active devices (e.g., diodes or transistors)). Embodiments of the fabric device also include power delivery networks, clocking, system management, and general-purpose I/O. A library includes mechanically and electrically interchangeable rotationally symmetrical chiplets that can be connected to the fabric device at one or more sites of an array of N×M sites. The rotational symmetry of the interface enables chiplets to be placed at any side of the fabric device. The modular chiplet system implements a shared memory architecture that allows the chiplets to communicate with each other using read/write transactions that are routed by the network-on-chip. The network-on-chip also enables communication between different resources of the fabric device. In some embodiments, bidirectional, low-latency 3D communication links connect the chiplets to the network-on-chip. The bidirectional link serializes memory access transactions across the 3D interface. The bidirectional link can be source synchronous or include clock data recovery. In some embodiments, a parallel source synchronous data bus is used to improve energy efficiency. A chiplet-based system-in-package designed using the modular chiplet system is programmable using memory mapped addressing.

The modular chiplet system uses three-dimensional integration to place active drivers and receivers close to an interconnect structure between the layers thereby reducing the lateral communication distance between chiplets from a few thousand micrometers to 100 μm or less. Rather than routing wires throughout a passive substrate (i.e., passive interposer), improved system performance and high frequency operation is achievable by routing packets using a network-on-chip in an active semiconductor substrate of a fabric device by a chiplet based SoC, which enables scaling of chiplets to larger systems.

The modular chiplet system combines a set of prefabricated fabric devices formed from a semiconductor substrate (e.g., small, medium, and large) with a predetermined set (e.g., 4, 16, or 64) of chiplet interfaces and a library of functional chiplets to serve a variety of system applications without requiring custom silicon devices. The modular chiplet system uses automated pick and place manufacturing to create systems of any volume, including a single unit, at the same cost. Thus, embodiments of the modular chiplet system described herein reduce design cost and time to market as compared to a custom-designed System-in-Package.

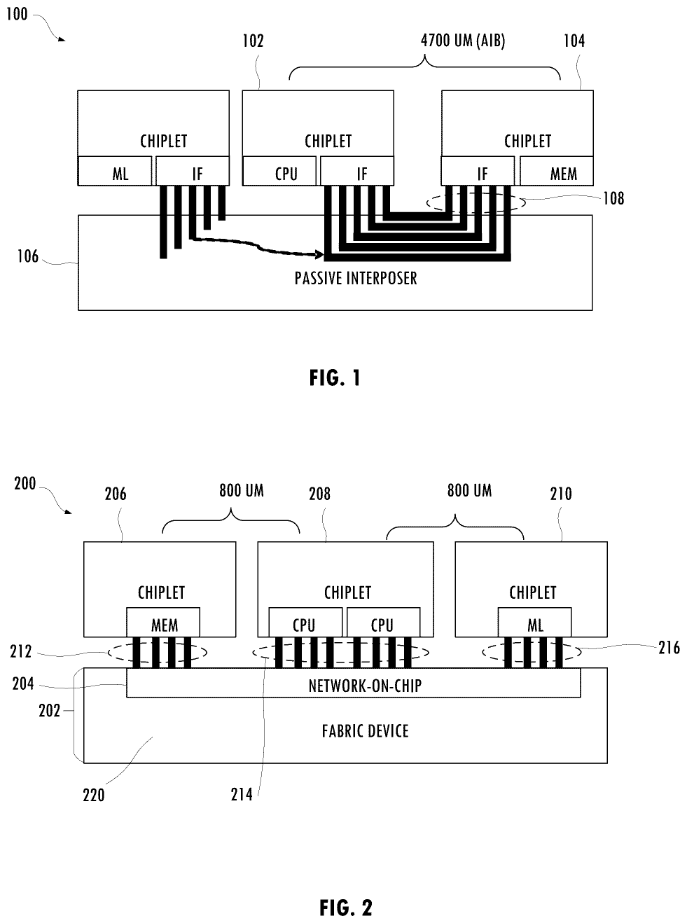

Referring to FIG. 2, integrated circuit product 200 includes fabric device 202 having network-on-chip 204, which is communicatively coupled to a plurality of chiplets via die-to-die interconnects (i.e., interconnects between stacked die that are formed using die-to-wafer or die-to-die attach processes, e.g., solder or hybrid bonding techniques). Fabric device 202 is made from semiconductor substrate 220 (e.g., silicon, aluminum oxide, sapphire, germanium, gallium arsenide, an alloy of silicon and germanium, or indium phosphide) and processed according to integrated circuit fabrication processes known in the art (e.g., multiple-step photolithographic and physicochemical processes such as thermal oxidation, thin-film deposition, ion implantation, etching, etc.) to form active semiconductor devices. In general, a network-on-chip is an in-chip network that couples separately designed blocks and components and routes data packets among them using switches. Chiplets 206, 208, and 210, each of which includes one or more functional units (e.g., memory, CPUs, or machine learning (ML) processors), are coupled to network-on-chip 204 via vertical interconnects 212, 214, and 216, respectively. Chiplets 206, 208, and 210 communicate with each other by sending and receiving packets via network-on-chip 204. Although integrated circuit product 200 may be implemented using an application-specific integrated circuit design flow, embodiments of integrated circuit product 200 designed using the modular chiplet system are designed using a library of pre-verified modules that are selected and assembled by a user to reduce cost and time-to-market of a system-in-package for a target application as compared to a custom-designed integrated circuit product. The fabric device including a network-on-chip allows for shorter wires (and thus reduces power consumption of interconnect), reduces complexity of physical interfaces, and simplifies chiplets. Integrated circuit product 200 has bandwidth limited by area, includes active signal routing (e.g., buffering), uses shorter effective distances of interconnect as compared to embodiments of the integrated circuit product using a passive interposer of FIG. 1.

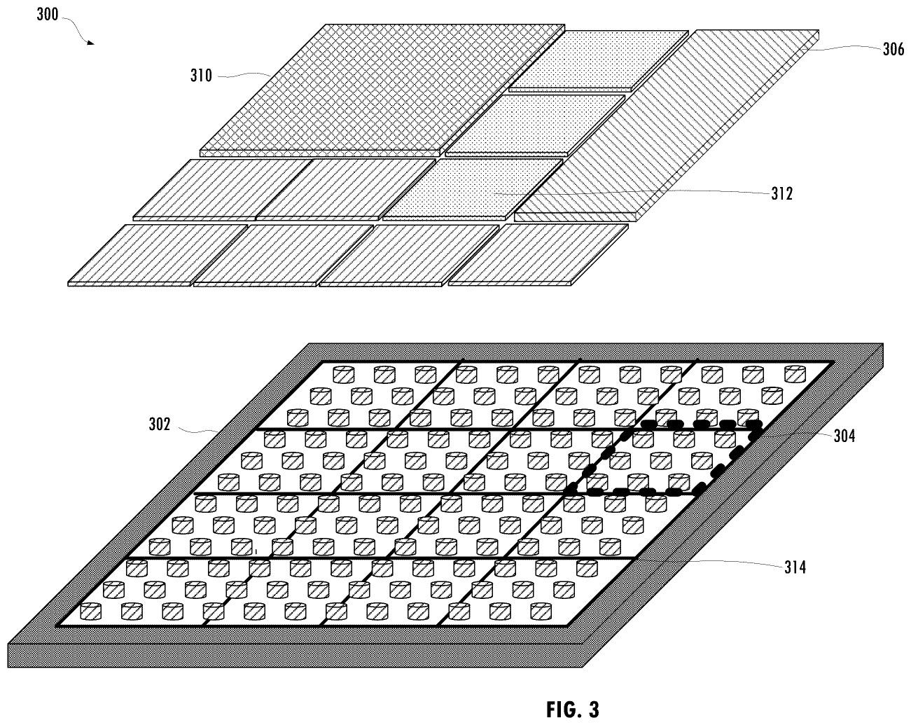

Referring to FIG. 3, fabric device 302 includes an active semiconductor substrate having a predetermined size (e.g., a small, medium, large, or extra large size). Fabric device 302 includes chiplet interfaces and provides functionality for communication (e.g., a network-on-chip) between those chiplet interfaces. In at least one embodiment, fabric device 302 includes interconnect for providing power supply and clocking from a fabric device to one or more chiplets. In at least one embodiment, fabric device 302 includes security and other control functionality. In at least one embodiment, fabric device 302 includes device I/O, e.g., a pad ring compliant with low voltage complementary metal oxide semiconductor (LVCMOS) circuits, high bandwidth interface circuits, pass through paths (e.g., SerDes or analog) from chiplets to package. In an embodiment, chiplets of type 306, 308, 310, and 312 are selected from a library of chiplets compatible with fabric device 302. In an embodiment, the library of chiplets includes at least one Central Processing Unit (CPU), Field Programmable Gate Array (FPGA), Digital Signal Processor (DSP), Neural Processing Unit (NPU), Intelligence Processing Unit (IPU), Machine Learning (ML) processor, Graphics Processing Unit (GPU), Static Random Access Memory (SRAM), Double Data Rate Synchronous Dynamic Random-Access Memory (DDR SDRAM), input/output (I/O) manager, Serializer/Deserializer (SerDes), Analog-to-Digital Converters (ADCs), Digital-to-Analog Converters (DACs), Non-Volatile Memory (NVM), or other functional modules. In an embodiment, the library of chiplets also includes a jumper chiplet. Each of the chiplets of type 306, 308, 310, and 312 includes one or more discrete chiplet interface corresponding to discrete chiplet interface 304.

Fabric device 302 includes a plurality of chiplet interfaces having a discrete size and pinout. Fabric device 302 includes one discrete chiplet interface 304 per tile of predetermined size in a tile grid of a surface of an active semiconductor substrate of fabric device 302. Embodiments of a fabric device include an N-by-M tile map (e.g., an N-by-M grid array) of discrete chiplet interface 304, where N and M are integers greater than or equal to one. Although the tile map is described as being a rectangular array, other embodiments use different geometric patterns (e.g. cross, rhombus, parallelogram, triangular, or irregular shapes). Each chiplet interface of the fabric device is separated from an adjacent chiplet interface by a lane (e.g., lane 314) having a predetermined width. For example, fabric device 302 includes a 4×4 grid of discrete chiplet interfaces 304. Each chiplet interface 304 includes at least pads for 3D attachment to a corresponding interface of a chiplet. In some embodiments, discrete chiplet interface 304 is compliant with a predetermined wafer-to-die or die-to-die interconnection specification (e.g., Universal Chiplet Interconnect Express (UCIe), The Bunch of Wires (BoW), Advanced Interface Bus (AIB), Open High Bandwidth Interface (HBI), Optical Internetworking Forum (OIF) Extra Short Reach (XSR), or other suitable wafer-to-die or die-to-die interconnection specification). In general, a substantial number of unique systems can be generated from a library of chiplets and a fabric device (e.g., up to N^{K} unique products, where N is the number of distinct chiplet designs in the chiplet library and K is the number of chiplet interfaces of the fabric device). Every chiplet in the chiplet library has a predetermined unit size or is an integer multiple thereof.

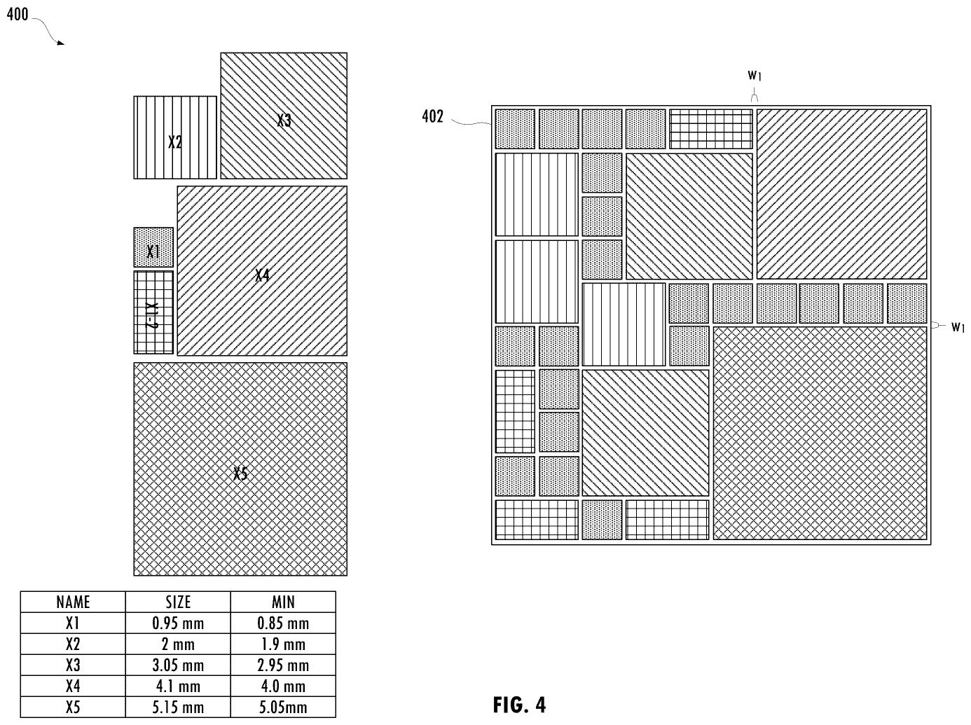

FIG. 4 illustrates modular chiplet system 400, which includes a library of chiplets having discrete sizes, X1, X2, X3, X4, and X5, which correspond to integer multiples of a unit size chiplet interface X1 and have total sizes of approximately integer multiples of that unit size X1. Sizes X2, X3, X4, and X5 include spacing (e.g., of width w₁) between individual chiplet interfaces of unit size X1. In an embodiment, unit size X1 has a size that corresponds to the size of one chiplet interface (e.g., 1 mm²) and a rectangular chiplet has size X1-2, which has a width of X1 and a length of X2. Accordingly, chiplets of any, or all, of the discrete sizes of modular chiplet system 400 can be arranged on a fabric device separated by predetermined space and are coupled to one or more corresponding chiplet interfaces of the fabric device. Fabric device 402 includes chiplets of all available predetermined sizes separated by predetermined spaces having width w₁ (e.g., 100 μm) and occupy all available chiplet interface sites of fabric device 402. However, in other embodiments, one or more predetermined sizes of chiplets are unused or one or more chiplet interface sites are unpopulated.

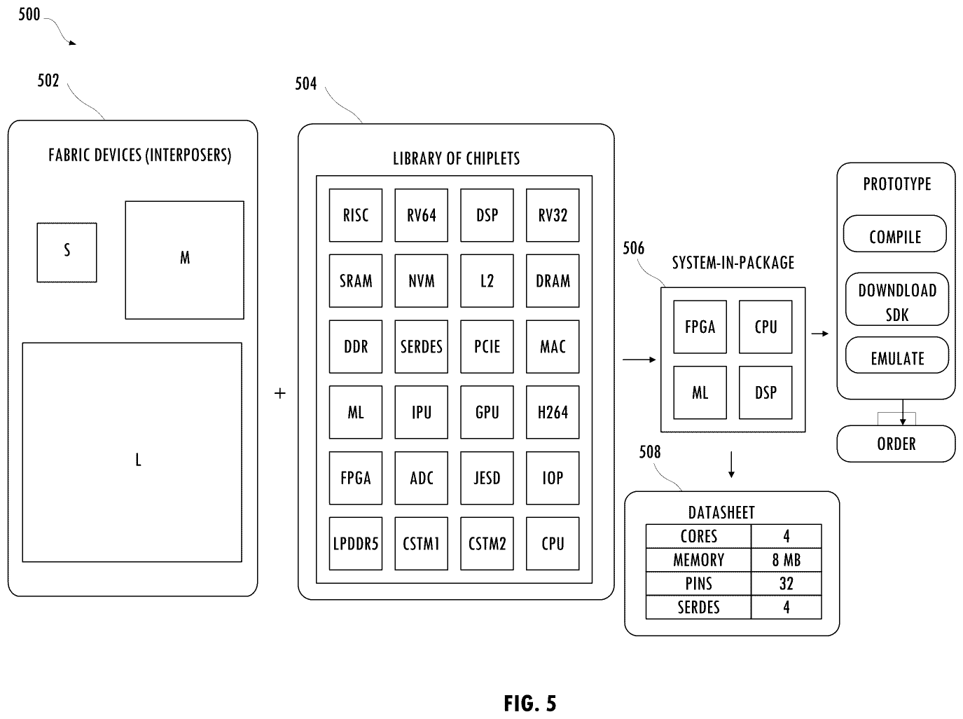

Referring to FIG. 5, in at least one embodiment, a modular chiplet system includes a library of fabric devices having a plurality of discrete sizes. For example, modular chiplet system 500 includes fabric device library 502 having three sizes of fabric devices (e.g., S, M, and L). A user of modular chiplet system 500 selects functional chiplets from library of chiplets 504 that achieve the functionality of a target application and selects a fabric device having a size sufficient to service selected chiplets to generate a target system-in-package. In at least one embodiment, software (e.g., a self-service web platform) is used to design system-in-package 506 using modular chiplet system 500, i.e., using library of chiplets 504 and fabric device library 502. In an embodiment, the software includes a user interface (e.g., a drag-and-drop interface referencing libraries of chiplets and fabric devices) and generates datasheet 508 describing features of system-in-package 506 (e.g., number of cores, amount of memory, number of pins, types of pins, etc.). In an embodiment, the software generates a register-transfer level model of the system-in-package for simulation. In an embodiment, a corresponding software development kit, emulator, and compiler for prototyping the system-on-chip generates a bill-of-materials and a purchase order for one or more manufactured devices (e.g., sample devices or production devices) of system-in-package 506.

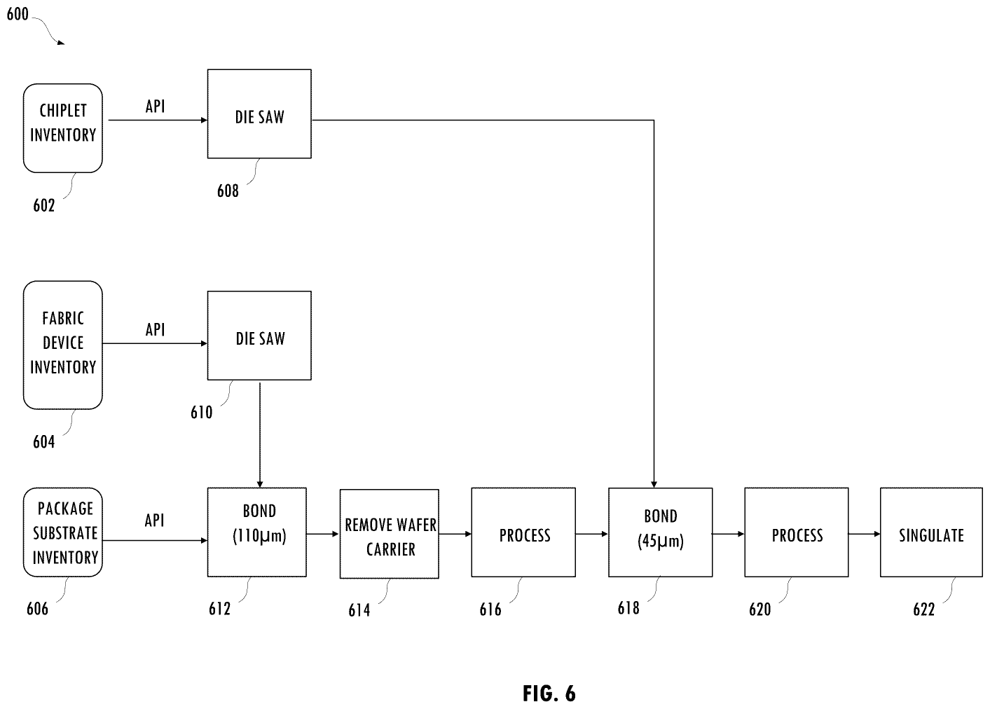

Referring to FIG. 6, in response to receiving a purchase order, software uses information in the purchase order and automation to fill the order, e.g., by communicating appropriate information to application programming interfaces that select specified chiplets and fabric devices from chiplet inventory 602 and fabric device inventory 604, respectively. The software selects suitable package substrates from package substrate inventory 606 and singulate corresponding devices (e.g., using die saw 608 or 610 or other suitable techniques known in the art). Singulated fabric devices are bonded to corresponding package substrates (612), any carrier wafers are removed (614), and additional packaging processes (616) are performed to prepare the fabric device for receiving one or more chiplets. One or more chiplets are assembled and bonded to the fabric device (618) and additional packaging processes (620) are performed to prepare the integrated circuit product before singulating individual packaged devices (622). The sequence of FIG. 6 is exemplary only and other sequences of manufacturing steps may be used to build to order integrated circuit products designed using the modular chiplet system described herein.

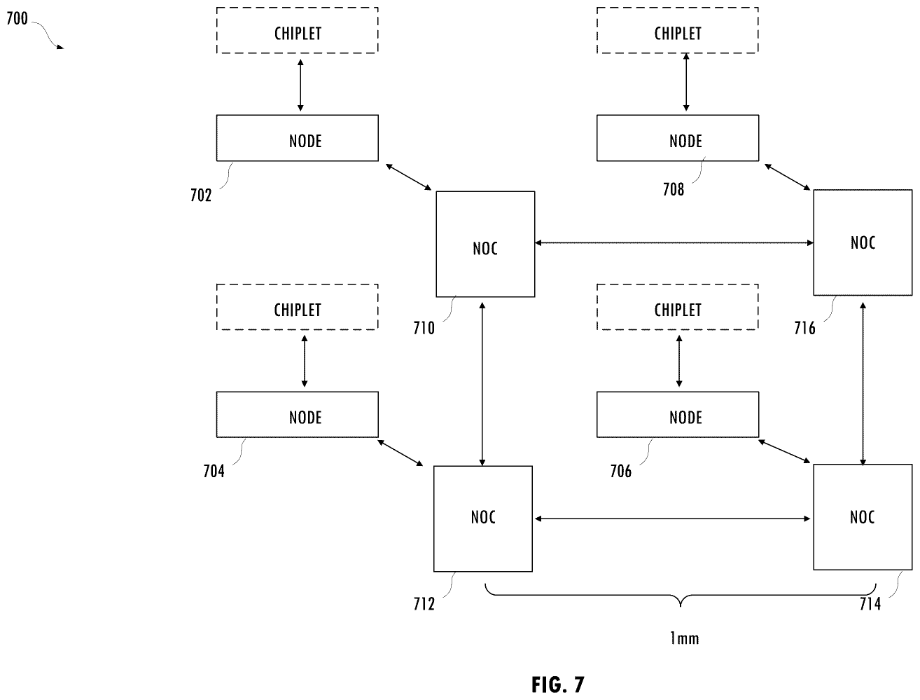

Embodiments of a fabric device of the modular chiplet system include a network-on-chip formed using a semiconductor substrate. Referring to FIG. 7, in general, a network-on-chip includes a reconfigurable interconnection of processing nodes (e.g., nodes 702, 704, 706, and 708), including corresponding chiplet interfaces and distributed storage elements, and I/O that are selectively coupled to each other (e.g., using switches). An exemplary implementation of a network-on-chip is described in U.S. Pat. No. 8,531,943, filed on Oct. 29, 2009, entitled “Mesh Network,” naming Andreas Olofsson as inventor, which application is hereby incorporated herein by reference. An exemplary embodiment of the network-on-chip is the Adapteva Inc. Epiphany-V, which includes an array of 1024 64-bit Reduced Instruction Set Computing (RISC) processors, 64 MB of on-chip SRAM, three 136-bit wide mesh networks-on-chip, and 1024 programmable I/O pins. An exemplary embodiment of network-on-chip 700 includes one network-on-chip node per mm² and uses 64-bit physical addressing, latency insensitive transactions, and bidirectional 2D mesh topology. In an embodiment, network-on-chip 700 uses independent physical networks-on-chip (e.g., network-on-chip 710, 712, 714, and 716) for requests and responses (e.g., read and writes), uses single cycle read/write transactions, supports high efficiency burst operations, deadlock free operation, single cycle ready/valid flow control, provides native support for atomic read/write operations, native multicast operations, vector interrupts, built-in error checking, and built-in traffic monitor and firewalls.

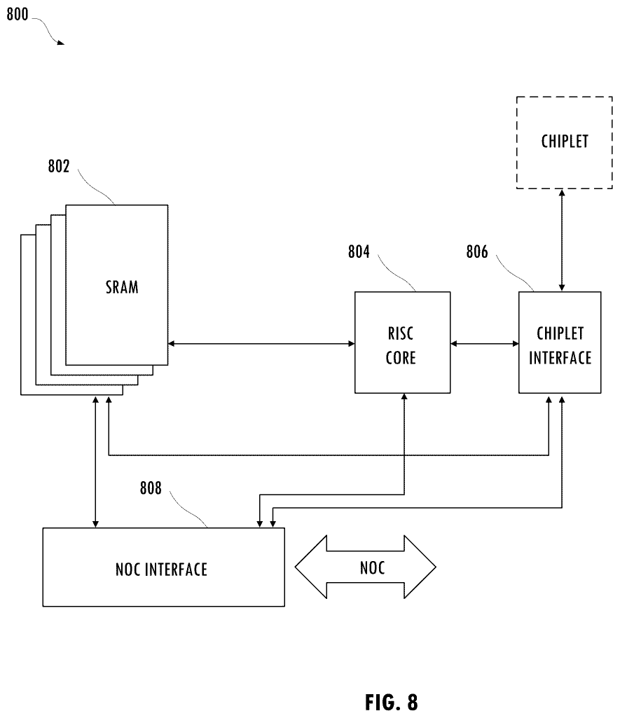

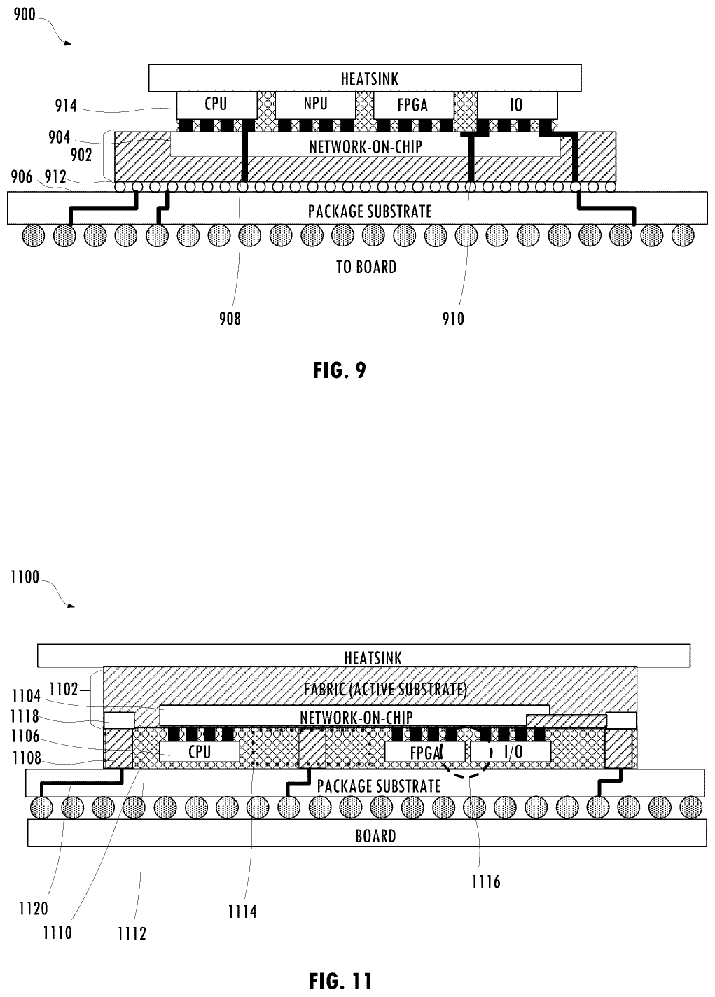

FIG. 8 illustrates an exemplary embodiment of a node in an embodiment of a network-on-chip of fabric device. Node 800 is a complete RISC processor capable of running an operating system and includes SRAM 802 which is a local, multi-bank SRAM that corresponds to a flat, cache-less distributed memory system that is readable and writeable by all nodes of the network-on-chip using direct memory access. Node 800 includes RISC core 804, chiplet interface 806 for 3D (i.e., vertical connection) to a chiplet, and network-on-chip interface 808 that couples node 800 to a cross bar switch to other nodes of the network-on-chip. Other embodiments of a fabric device use different embodiments of network-on-chip architectures and network-on-chip nodes.

Referring to FIG. 9, in at least one embodiment, integrated circuit product 900 includes fabric device 902, which includes network-on-chip 904. Fabric device 902 is formed from an active semiconductor substrate including through-silicon vias (TSVs) 908 and 910 for power I/O (e.g., VDD and VSS). Chiplet I/O are coupled to chiplet interfaces (not shown) via vertical interconnect. Network-on-chip 904 provides all communications between chiplets. System I/O are coupled between fabric device 902 and package substrate 906 via conductive bumps 912 (e.g., C4 bumps), conductive pillars, or other suitable conductive structure known the in art. Package substrate 906 includes through-substrate conductors that couple conductors on the front side of fabric device 902 (e.g., conductive bumps 912) to conductors (e.g., solder balls) on the back side of fabric device 902 for coupling system I/O between fabric device 902 and a printed circuit board. In an embodiment, various chiplets 914 are vertically attached to network-on-chip 904 (e.g., stacked with network-on-chip 904 and coupled using conductive pillars, conductive microbumps, or other suitable conductive structure known the in art). Chiplets 914 have discrete sizes (e.g., 2 mm²) and may have heterogeneous functions (e.g., CPU, NPU, FPGA, and I/O). Chiplets 914 are attached face-to-face with fabric device 902 and encapsulated. That is, active semiconductor substrate of fabric device 902 is between the front side of chiplets 914 and package substrate 912. A heatsink is attached to the back side of chiplets 914.

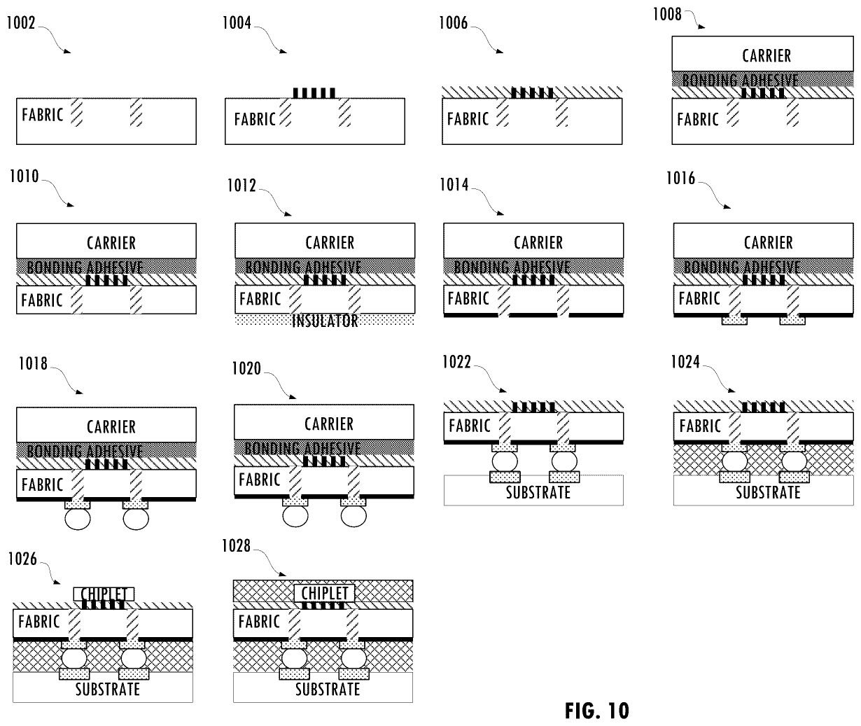

FIGS. 9 and 10 provide an overview of integrated circuit product 900 and an exemplary integrated circuit manufacturing process for packaging embodiments of integrated circuit product 900. Fabric device 902, which includes TSVs 908 and 910, is formed using an active semiconductor substrate (1002). Conductive bumps are formed on the front side of the fabric device 902 (i.e., the side of fabric device used to form network-on-chip 904) (1004). Those conductive bumps are encapsulated (1006) and a carrier substrate is bonded to the encapsulated front side bumps (1008). A TSV reveal process grinds and etches the back side of the active semiconductor substrate of the fabric device 902 to expose the TSVs on the back side of fabric device 902 (1010). The back side of fabric device 902 is passivated with an insulating material (1012) and a second TSV reveal process is performed (e.g., etches the back side of the fabric device 902) (1014). Conductive pads coupled to the TSVs are formed on the back side of the fabric device (1016) and conductive structures (e.g., conductive bumps) are formed in contact with the conductive pads (1018). Fabric device 902 is singulated from the remainder of the active semiconductor substrate (1020). The carrier substrate is removed from the front side of fabric device 902 and fabric device 902 is attached to pads of package substrate 906 (1022). Underfill is applied between fabric device 902 and package substrate 906 (1024). Chiplets 914 are bonded to the front side bumps of fabric device 902 and mold or underfill material is applied to mechanically stabilize the chiplets before attaching a heatsink (1028). The steps of FIG. 10 are exemplary only and other materials and packaging processes may be used to form an integrated circuit product including a fabric device having TSVs and chiplets consistent with the modular chiplet system described herein.

In general, forming TSVs in the active semiconductor substrate of a fabric device is a relatively expensive process that may be available only from a limited number of providers and for a limited selection of process nodes. Qualification of TSVs for high volume manufacturing using the newest process nodes typically lags availability of the newest process nodes for high volume manufacturing in general. Therefore, embodiments of the fabric device that do not use TSVs can reduce the cost of manufacturing a fabric device and thus reduce the cost of the final integrated circuit product. Referring to FIG. 11, in at least one embodiment of an integrated circuit product, fabric device 1102 includes network-on-chip 1104. Network-on-chip 1104 is coupled to chiplets 1106 (e.g., CPU, FPGA, and I/O chiplets) via chiplet interfaces (not shown) and vertical interconnect (e.g., conductive pillars, conductive microbumps, or other suitable conductive structure known the in art). Mold encapsulant 1110 is applied to chiplets 1106 and through mold vias 1108 are formed in mold encapsulant 1110. A module including fabric device 1102 and encapsulated chiplets 1106 is attached to package substrate 1112 with the front side of fabric device 1102 facing package substrate 1112 and the back side of chiplets 1106 facing package substrate 1112. That is, chiplets 1106 are disposed between package substrate 1112 and active semiconductor substrate of fabric device 1102. Other vertical conductive structures known in the art may be included to couple through mold vias 1108 to conductive structures on package substrate 1112. Package substrate 1112 includes through-substrate conductors 1120 that couple conductors on the front side of package substrate 1112 to conductors on the back side of the package substrate and couple I/O to a printed circuit board. In an embodiment, various chiplets 1106 are discrete sizes (e.g., 2 mm²) and are coupled to corresponding chiplet interfaces of fabric device 1102 and are spaced by predetermined width 1116 from each other. However, a chiplet interface (i.e., a chiplet placement site) and associated chiplet interface may or may not be populated. For example, placement site 1114 is depopulated but includes through mold vias and encapsulant.

In at least one embodiment, fabric device 1102 includes at least one additional interface that is electrically coupled to network-on-chip 1104. Interface 1118 includes boundary pads formed in the active semiconductor substrate of fabric device 1102, disposed adjacent to network-on-chip 1104, and coupled laterally to network-on-chip 1104 with respect to the front side of the active semiconductor substrate of fabric device 1102. Interface 1118 receives system I/O from a printed circuit board using through mold vias 1108 in encapsulant 1110 and does not require TSVs in fabric device 1102. In other embodiments (e.g., embodiments having the back side of a fabric device attached to a package substrate), TSVs and other vertical interconnect (e.g., conductive bumps) couple interface 1118 to a package substrate, which couples interface 1118 to a printed circuit board or other devices coupled to the package substrate (e.g., via vertical interconnect).

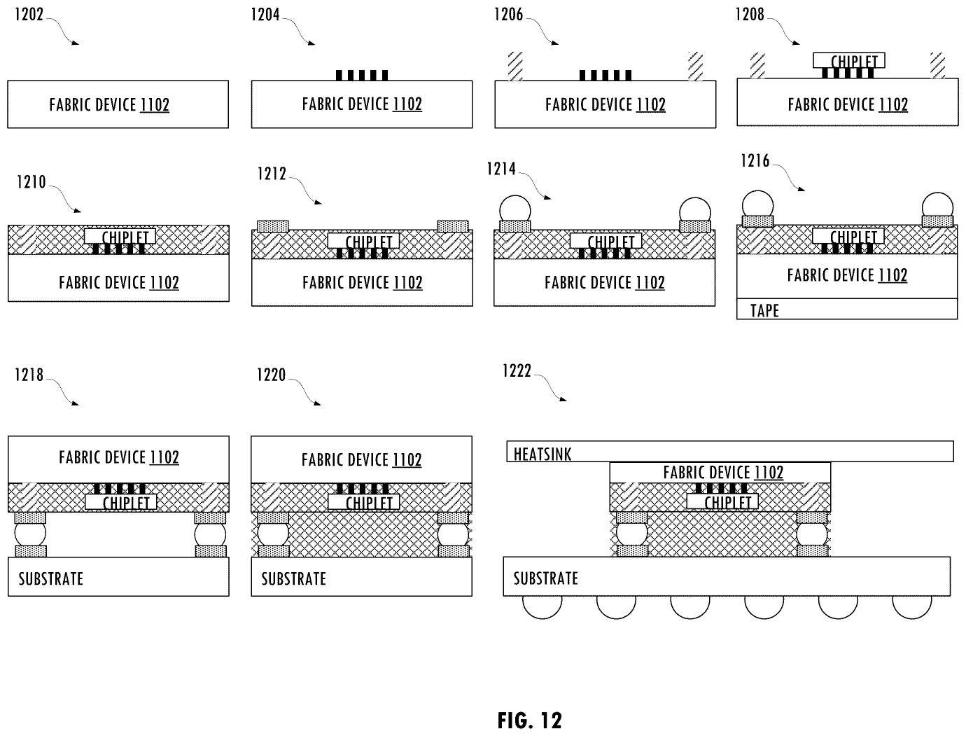

Referring to FIGS. 11 and 12 an exemplary integrated circuit packaging process for manufacturing integrated circuit product 1100 includes forming fabric device 1102 including network-on-chip 1104 without any TSVs using known integrated circuit manufacturing techniques (1202). First vertical conductive structures (e.g., microbumps) are formed on the front side of fabric device 1102 using a mask and associated techniques known in the art (1204). Additional vertical conductive structures (e.g., megabumps) are formed on the front side of fabric device 1102 using an additional mask and associated techniques known in the art (1206). One or more chiplets are attached to the first vertical structures (1208) and mold or underfill material is applied to mechanically stabilize the chiplets. That underfill material is ground to expose the additional vertical conductive structures (1210). Conductive pads are formed coupled to the additional vertical conductive structures using a mask and associated techniques known in the art (1212). Conductive balls (e.g., C4 balls) are attached to the pads (1214). The fabric device is singulated from the remainder of the active semiconductor substrate (1216). The fabric device is flip chip attached to pads of package substrate 1112 (1218). Underfill is applied between the encapsulated chiplets and package substrate 1112 (1220). A heatsink is attached to the back side of fabric device 1102 and conductive balls are attached to the back side of the package substrate (1222). The steps of FIG. 12 are exemplary only and other materials and manufacturing processes may be used to form integrated circuit product 1100, which includes chiplets and a fabric device without TSVs through the active semiconductor substrate consistent with the modular chiplet system described herein. The exclusion of TSVs in fabric device 1102 reduces cost and broadens the number of integrated circuit manufacturing providers or process nodes that may be used to manufacture fabric device 1102.

In an embodiment, the modular chiplet system uses rotationally symmetrical interfaces (e.g., rotationally symmetrical pinout of conductive pads, balls, or other structure) to communicate between the chiplets and the fabric device. The rotationally symmetrical interface is used to physically attach and electrically connect conductors (e.g., conductive traces for power, ground, clocks, transmit or receive data buses, etc.) of a chiplet to corresponding conductors of a fabric device. The rotational symmetry enables I/O chiplets to be placed at any interface site of the fabric device and with more than one orientation at that site, which increases chiplet density of an integrated circuit production some embodiments. As referred to herein, rotational symmetry of a chiplet interface refers to the ability of the chiplet interface to be rotated by less than one full turn about an axis of symmetry (e.g., an axis through the center of the chiplet interface) and still look the same and be capable of being coupled to corresponding conductors of the fabric device. For example, a chiplet interface having second order rotational symmetry can be rotated by 180 degrees and I/Os of the chiplet interface will still align with corresponding I/Os of the fabric device.

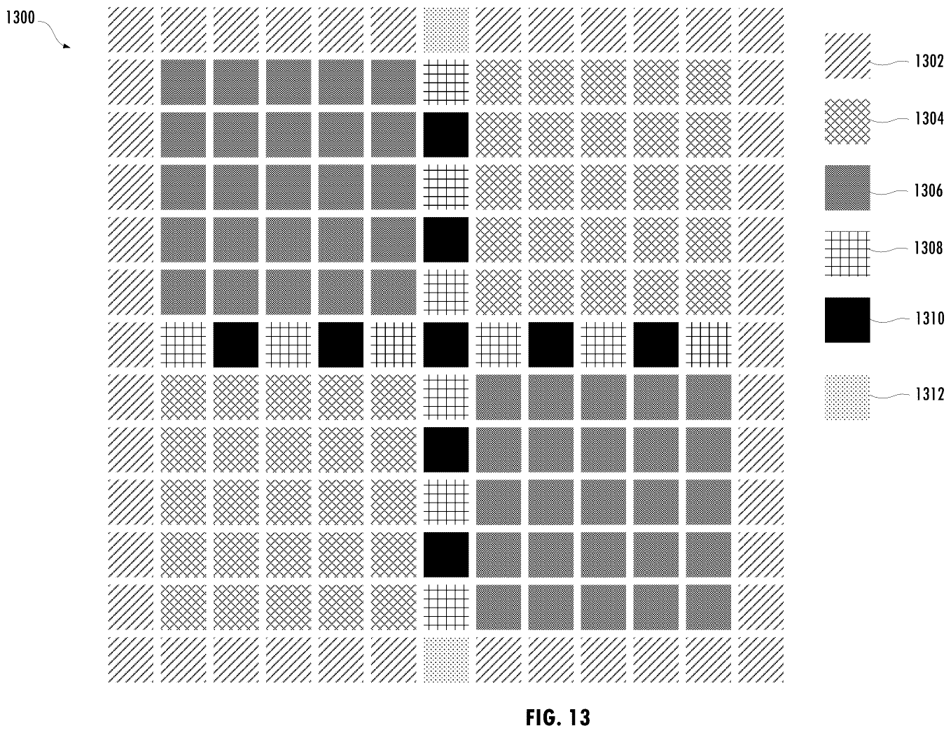

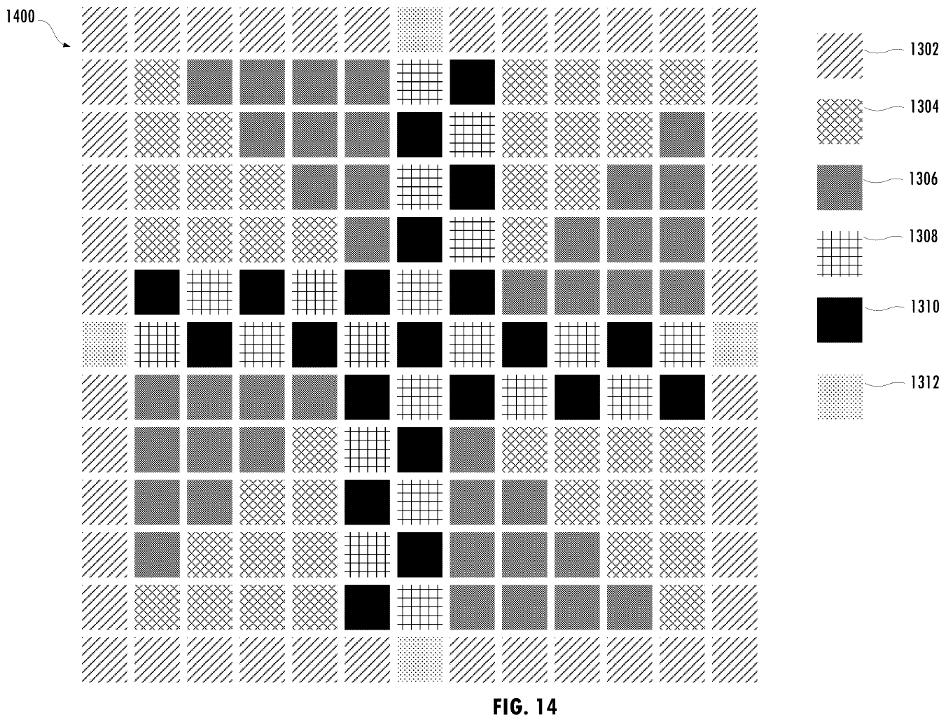

Referring to FIGS. 13 and 14, exemplary interfaces 1300 and 1400 include 13×13 grid arrays of connectors corresponding to pinouts of different signal types, e.g., pins with type 1302 correspond to general-purpose I/O signals, pins with type 1304 correspond to transmit signals, pins with type 1306 correspond to receive signals, pins with type 1308 correspond to VDD signals, pins with type 1310 correspond to VSS signals, and pins with type 1312 correspond to clock signals. Interface 1300 has second order rotational symmetry, i.e., a chiplet having interface 1300 can be rotated by 180 degrees and pins of type 1302, 1304, 1306, 1308, 1310, and 1312 will still land on contacts of type 1302, 1304, 1306, 1308, 1310, and 1312, respectively. Interface 1400 has fourth order rotational symmetry, i.e., interface 1400 can be rotated by 90 degrees and pins of type 1302, 1304, 1306, 1308, 1310, and 1312 of interface 1400 will still land on contacts of the fabric device having type 1302, 1304, 1306, 1308, 1310, and 1312, respectively.

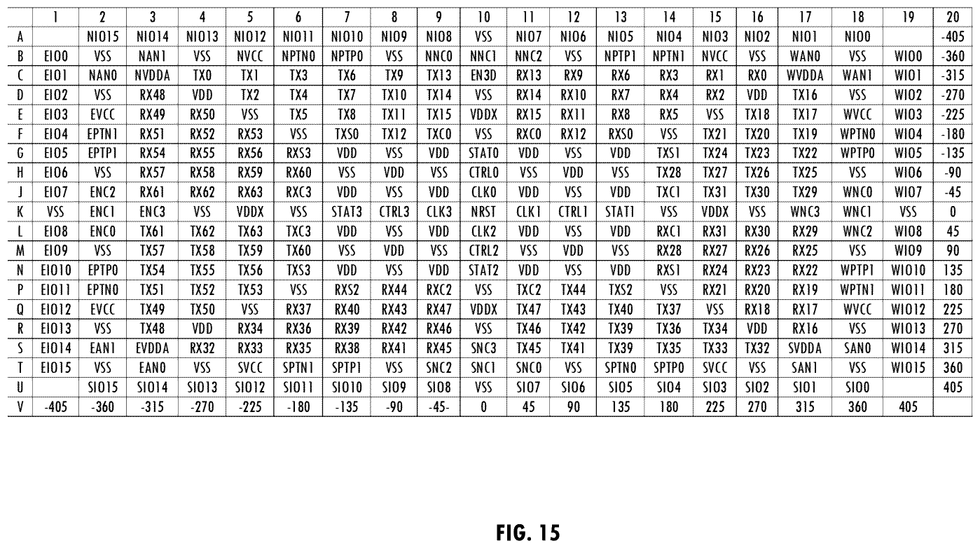

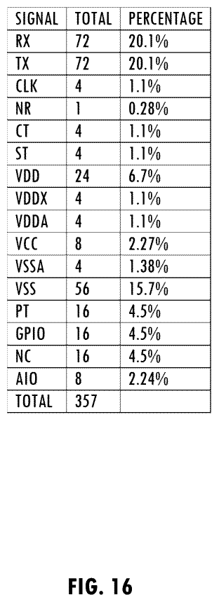

FIGS. 15 and 16 illustrate an exemplary standardized pinout for chiplets having fourth order rotational symmetry. A 19×19 grid array of pins uses 357 pins for receive (RX), transmit (TX), clock (CLK), reset (NR), control (CT), status (ST), digital power supply voltage (VDD), interface supply voltage (VDDX), analog power supply voltage (VDDA), analog power supply voltage (VCC), analog ground (VSSA), digital ground (VSS), pass through for non-standard analog (PT), general-purpose I/O (GPIO), no connect (NC), and analog I/O (AIO). In at least one embodiment, logical mapping of the bit indices of a pins-to-bus mapping is runtime configurable according to the orientation of each chiplet on the fabric device. In an embodiment, a programmable bus is hardcoded during manufacture but after testing by using fuses or other one-time programmable technique. In an embodiment of the modular chiplet system, the pinout of FIG. 15 repeated for each 1 mm² tile of the fabric device. In an embodiment, each 1 mm² tile of the fabric device is separated from an adjacent tile of the fabric device by a lane having a predetermined width. Although the pinouts are described as being arranged in a rectangular or square pattern, in other embodiments the pinout arrangement forms different geometric shapes (e.g. cross, rhombus, parallelogram, triangular, or irregular shapes).

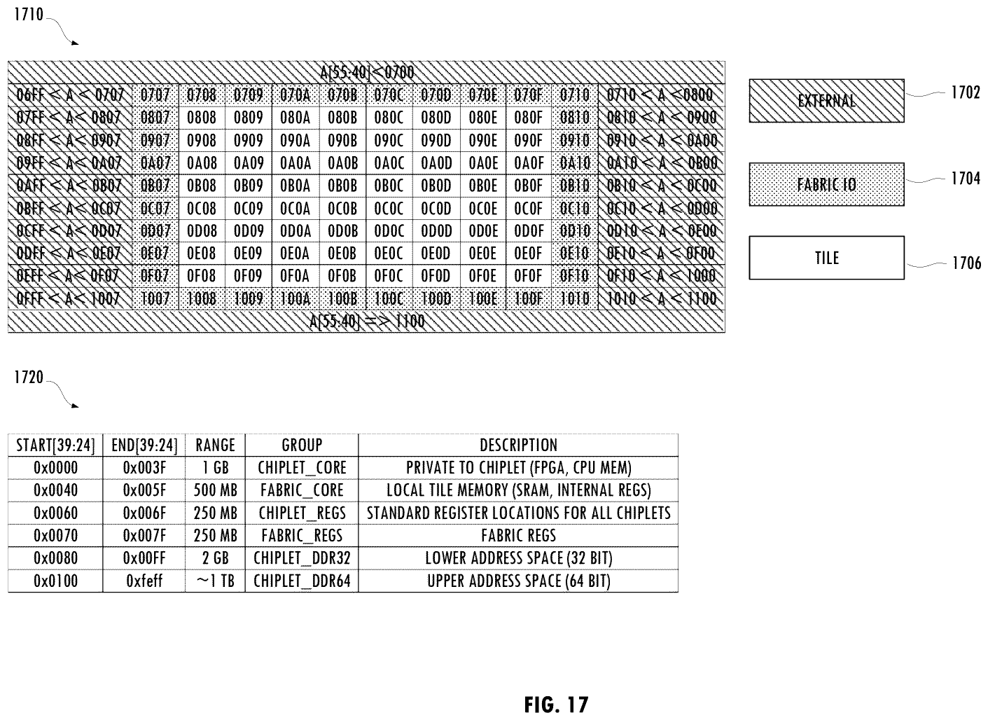

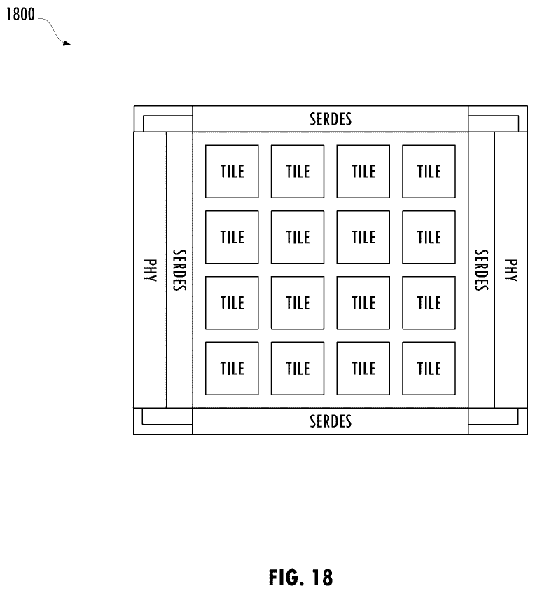

In an embodiment, the modular chiplet system uses memory mapped addressing for accessing each chiplet coupled to an interface disposed in a site of an N-by-M tile map of the chiplet interfaces of a fabric device. The chiplets communicate with each other using read or write transactions to memory mapped addresses that are routed by the network-on-chip. Referring to FIGS. 17 and 18, table 1710 illustrates most-significant bits of an address in an exemplary memory map for accessing each chiplet or discrete chiplet interface using 56-bit physical memory addressing of an exemplary fabric device having a 4×4 tile map of chiplet interfaces. Fabric device 1800 of FIG. 18 includes an active semiconductor substrate having a 64-node network-on-chip with RISC-V standard controller cores, 32 MB of local SRAM, two physical layer interfaces for connecting chiplets to the MAC of the Open Source Initiative (OSI) reference model, and four SerDes interfaces. The most-significant bits of the memory address are listed in the table and specify which external I/O, fabric device I/O registers, or chiplet interface is being accessed. Memory regions corresponding to system I/O are type 1702, fabric device I/O are type 1704, and chiplet tile external I/O are type 1706. Each chiplet in a tile uses four memory regions. For example, one tile (i.e., one chiplet) corresponds to memory regions mapped to addresses with most significant bits A [55:40]=0E0E, 0E0F, 0F0E and 0F0F. Table 1720 further describes address bits A [39:0] of the exemplary 56-bit physical memory address map for fabric device registers and chiplets. The memory map of FIGS. 17 and 18 is exemplary only and addressing may vary with system topology.

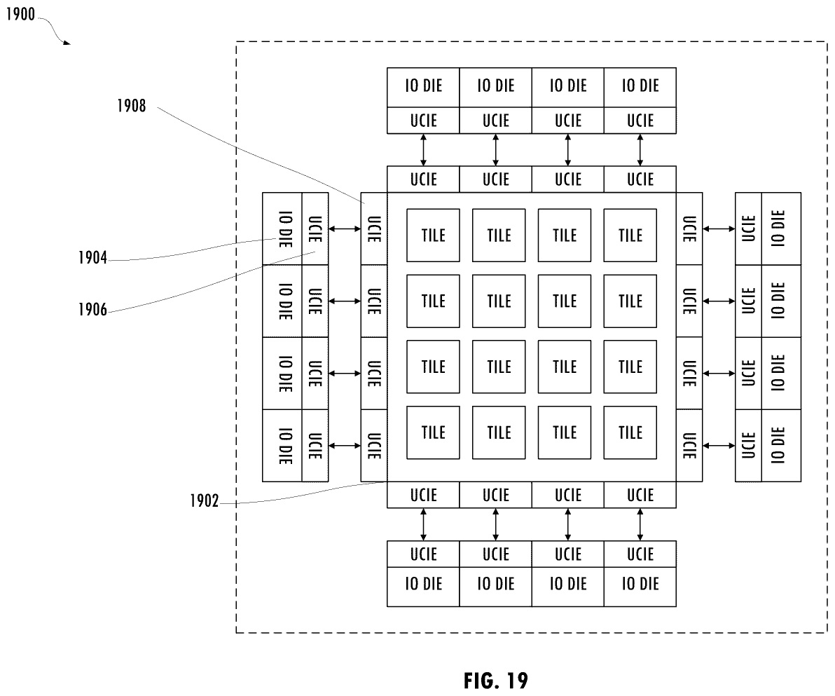

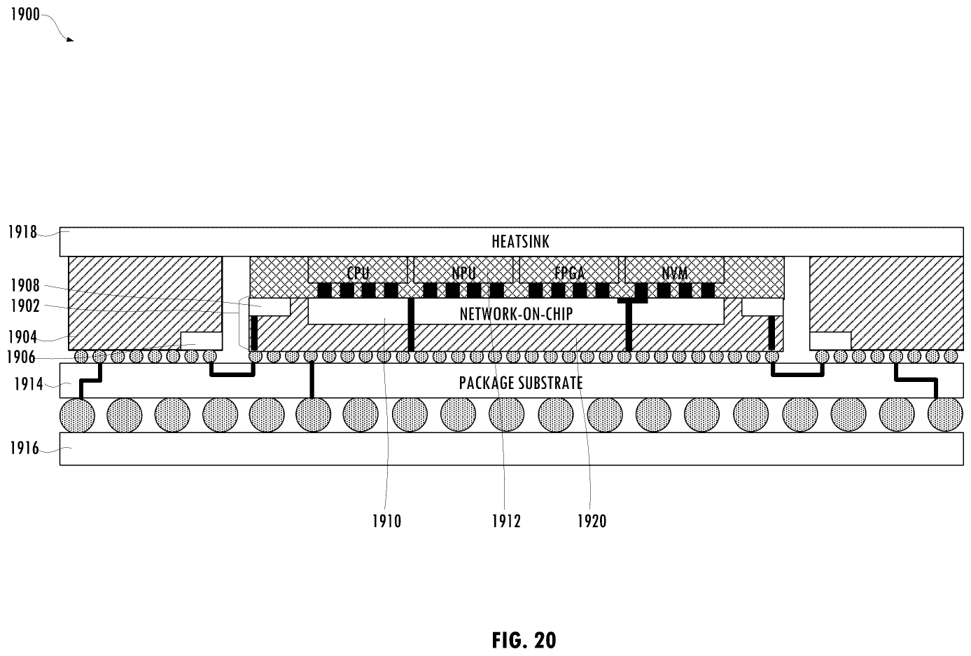

In at least one embodiment, a modular chiplet system includes 2D integration with other devices or chiplets. For example, FIGS. 19 and 20 illustrate a plan view and a cross-sectional view, respectively, of integrated circuit product 1900 including 3D interfaces to chiplets stacked with fabric device 1902 and 2D links between a standard chiplet interface of fabric device 1902 to a standard interface of I/O chiplets disposed laterally adjacent to fabric device 1902 with respect to package substrate 1914. Fabric device 1902 includes semiconductor substrate 1902 having a 4×4 tile map of chiplet interfaces for 3D connections to chiplets 1912 stacked with fabric device 1902 and 16 standard UCIe interfaces 1908 for 2D connections to standard UCIe interfaces 1906 of I/O chiplets 1904 disposed laterally adjacent to fabric device 1902 with respect to package substrate 1914. An active semiconductor substrate of fabric device 1902 includes network-on-chip 1910, which in an embodiment includes 16 MB of distributed SRAM, 64 in-order RISC-V CPU management cores.

In at least one embodiment, network-on-chip 1910 has an integrated circuit design that exceeds a reticle limit of the manufacturing technology used to manufacture network-on-chip 1910 and the integrated circuit design is formed by a first integrated circuit die of semiconductor substrate 1902 and at least one other integrated circuit die of semiconductor substrate 1902. Accordingly, in addition to other functionality (e.g., CPU, NPU, FPGA, NVM functionality) of chiplets 1912, at least one of chiplets 1912 is configured as a jumper chiplet that spans a scribe line between the first integrated circuit die and the other integrated circuit die. A first portion of the jumper chiplet is stacked with a first portion of the first integrated circuit die, and a second portion of the jumper die is stacked with a first portion of the other integrated circuit die.

Thus, embodiments of the modular chiplet system have been described. The modular chiplet system reduces design cost and time to market of a newly developed system-in-package as compared to a custom-designed system-in-package. The description of the invention set forth herein is illustrative and is not intended to limit the scope of the invention as set forth in the following claims. The terms “first,” “second,” “third,” and so forth, as used in the claims, unless otherwise clear by context, are to distinguish between different items in the claims and do not otherwise indicate or imply any order in time, location, or quality. For example, “a first received signal” and “a second received signal,” do not indicate or imply that the first received signal occurs in time before the second received signal. Variations and modifications of the embodiments disclosed herein may be made based on the description set forth herein, without departing from the scope of the invention as set forth in the following claims.

What is claimed is:

1. An integrated circuit product comprising:
an active semiconductor substrate comprising:
a network-on-chip; and
a plurality of die interfaces coupled to the network-on-chip,
wherein each die interface of the plurality of die interfaces is disposed in a corresponding tile of an N-by-M tile map of a surface of the active semiconductor substrate and each die interface of the plurality of die interfaces is separated from an adjacent die interface of the plurality of die interfaces by a lane having a predetermined width,
wherein N and M are integers of at least one.

2. The integrated circuit product as recited in claim 1 wherein each die interface of the plurality of die interfaces has a grid array of connectors with a predetermined rotationally symmetric pinout.

3. The integrated circuit product as recited in claim 2 wherein a type of each connector of the grid array of connectors is the same type as a corresponding connector at a location of a predetermined number of degrees of rotation around an axis of symmetry from the predetermined rotationally symmetric pinout.

4. The integrated circuit product as recited in claim 2 further comprising:
an integrated circuit die comprising a rotationally symmetric die interface including at least one grid array of connectors, wherein the rotationally symmetric die interface is coupled to at least one corresponding die interface of the plurality of die interfaces.

5. The integrated circuit product as recited in claim 4 wherein the integrated circuit die has a size corresponding to multiple adjacent die interfaces of the plurality of die interfaces and one or more lanes between the multiple adjacent die interfaces.

6. The integrated circuit product as recited in claim 4 wherein the integrated circuit die further comprises:
a programmable bus; and
a rotationally symmetric pinout,
wherein the programmable bus is configured to logically map the rotationally symmetric pinout to the predetermined rotationally symmetric pinout.

7. The integrated circuit product as recited in claim 4 wherein the integrated circuit die is configured to communicate with a second integrated circuit die coupled to a second corresponding die interface of the plurality of die interfaces using request-response memory transactions via the network-on-chip.

8. The integrated circuit product as recited in claim 1 wherein N and M are integers greater than one.

9. The integrated circuit product as recited in claim 1 wherein each die interface of the plurality of die interfaces has a corresponding address in a memory map of the N-by-M tile map of the surface of the active semiconductor substrate.

10. The integrated circuit product as recited in claim 1 wherein the network-on-chip is coupled to a first die interface of the plurality of die interfaces vertically with respect to a front side of the active semiconductor substrate and the active semiconductor substrate further comprises at least one input/output interface and the network-on-chip is coupled to the at least one input/output interface laterally with respect to the front side of the active semiconductor substrate.

11. The integrated circuit product as recited in claim 1 wherein the active semiconductor substrate further comprises:
at least one power delivery network coupled to the plurality of die interfaces; and
at least one general-purpose input/output coupled to the plurality of die interfaces.

12. An integrated circuit product comprising:
an integrated circuit die comprising:
a die interface including a grid array of connectors; and
a programmable bus configured to logically map the grid array of connectors to a predetermined rotationally symmetric pinout.

13. The integrated circuit product as recited in claim 12 wherein the die interface has a predetermined size and the integrated circuit die comprises at least one additional die interface having the predetermined size and being disposed laterally with respect to the die interface and is separated from the die interface by a lane having a predetermined width.

14. The integrated circuit product as recited in claim 12 further comprising:
an additional integrated circuit die; and
an active semiconductor substrate comprising:
a network-on-chip; and
a plurality of die interfaces coupled to the network-on-chip, each die interface of the plurality of die interfaces having a corresponding grid array of connectors with a corresponding predetermined rotationally symmetric pinout,
wherein the integrated circuit die is coupled to the additional integrated circuit die using at least one of the plurality of die interfaces and the network-on-chip.

15. The integrated circuit product as recited in claim 14 wherein each die interface of the plurality of die interfaces is accessible by a corresponding address in a memory map of an N-by-M tile map of a surface of the active semiconductor substrate.

16. The integrated circuit product as recited in claim 15 wherein the integrated circuit die is configured to communicate using request-response memory transactions via the die interface.

17. The integrated circuit product as recited in claim 12 wherein the integrated circuit die further comprises a general-purpose input/output pad ring.

18. A method of manufacturing an integrated circuit product comprising:
attaching a plurality of integrated circuit die to an active semiconductor substrate using a plurality of corresponding integrated circuit die interfaces,
wherein each integrated circuit die of the plurality of integrated circuit die has a size that is at least an integer multiple of a minimum predetermined die size, and
wherein the active semiconductor substrate includes a network-on-chip and has a surface with an N-by-M tile map of the plurality of corresponding integrated circuit die interfaces.

19. The method as recited in claim 18 wherein each of the plurality of corresponding integrated circuit die interfaces has a predetermined rotationally symmetric pinout and the method further comprises:
programming a programmable bus of each integrated circuit die of the plurality of integrated circuit die to logically map a corresponding rotationally symmetric pinout to the predetermined rotationally symmetric pinout according to an orientation of the integrated circuit die with respect to the active semiconductor substrate.

20. The method as recited in claim 18 further comprising:
attaching an additional integrated circuit die to the network-on-chip using an input/output interface of the active semiconductor substrate,
wherein the additional integrated circuit die is disposed laterally adjacent to the integrated circuit die with respect to a front side of the active semiconductor substrate, and
wherein the network-on-chip is coupled to a first die interface of the plurality of corresponding integrated circuit die interfaces vertically with respect to the front side of the active semiconductor substrate.

21. The integrated circuit product formed by the method as recited in claim 18.
